(19) United States
(12) Patent Application Publication
(10) Pub. No.: US 2004/0044486 A1
(43) Pub. Date: Mar. 4, 2004

(54) Non-linear electronics for sensing maximum dynamic range

(76) Inventor: Michael S. Tignor, Watertown, CT (US)

Correspondence Address: JOHN S. BEULICK, C/O ARMSTRONG TEASDALE, LLP, ONE METROPOLITAN SQUARE, SUITE 2600, ST LOUIS, MO, 63102-2740, US

(21) Appl. No.: 10/064,949

(22) Filed: Sep. 3, 2002

(51) Int. Cl. G01R 19/00; G06F 19/00

(52) U.S. Cl. 702/64

(57) ABSTRACT

A current sensing method in an electronic trip unit is described. The method includes the steps of sensing an electrical current and generating an analog input signal having a first amplitude portion and a second amplitude portion that is different than the first amplitude portion, compressing the analog input signal non-linearly by amplifying the first amplitude portion of the analog input signal greater than the second amplitude portion of the analog input signal, and generating a trip signal when any portion of the analog input signal is greater than a pre-determined limit.

### BACKGROUND OF INVENTION

This invention relates generally to electronic trip units (ETU), and more particularly to a method and an apparatus for sensing a maximum dynamic range of electrical signals by an electronic trip unit.

Electronic trip units (ETU) are well known in the art for protecting electrical components. At least some known electronic trip units include a current sensor which provides analog signals indicative of the power line electrical current to an analog to digital (A/D) converter. The A/D converter converts the signals to digital signals which are processed by a microprocessor. The trip unit also includes random access memory (RAM), read only memory (ROM) and electronic erasable programmable read only memory (EEPROM), all of which interface with the microprocessor. An output of the electronic trip unit actuates a circuit breaker that includes a plurality of contact pairs which allows current to pass from one contact member to another contact member. More specifically, when the contacts open, current is prevented from flowing from one contact member to the other and therefore, current is prevented from flowing to a load connected to the breaker.

The electronic trip unit measures the current flowing through a circuit breaker and may trip the circuit breaker in response to current measured outside predetermined parameters set in the ETU. As such, the trip unit needs to accurately sense and measure currents over a wide dynamic range, and generally, smaller currents need to be characterized with greater precision than very large currents, because smaller currents are measured with a RMS based algorithm while the larger currents are measured with a peak algorithm. Further more, electronic trip units need to measure currents over a wide dynamic range. It is not uncommon for this dynamic range to be one hundred to one or more. If such a dynamic range is linearly spread across an A/D converter range, it may reduce an overall precision below the point that proper accuracy is not achievable.

Previous products obtain current measurements using amplifiers that include more than one channel. For example, a high gain channel is used for low currents, and a low gain channel is used for high currents. The microprocessor in the ETU reassembles the digitized signal to provide a proper weighting to the sampled data. However, such an approach may provide discontinuous data due to matching errors with the amplifiers. Another problem with such an approach is that more than one digitization interval may be needed for each sampled point.

### SUMMARY OF INVENTION

In one aspect, a method of current sensing in an electronic trip unit is provided. The method includes the steps of sensing an electrical current and generating an analog input signal having a first amplitude portion and a second amplitude portion that is different than the first amplitude portion, compressing the analog input signal non-linearly by amplifying the first amplitude portion of the analog input signal greater than the second amplitude portion of the analog input signal, and generating a trip signal when any portion of the analog input signal is greater than a pre-determined limit.

In another aspect, an electronic trip unit is provided including a sensor for sensing an electrical current and generating an analog input signal having a first amplitude portion and a second amplitude portion that is different than the first amplitude portion, a compressor circuit electrically coupled to the sensor for amplifying the first amplitude portion of the analog input signal greater than the second portion of the analog input signal, and a microprocessor responsive to the digital signal, the microprocessor includes a memory for storing program signals defining an executable program code for decompressing the digital signal, the microprocessor also generates a trip signal when the digital signal is greater than a pre-determined value.

In a further aspect, an electrical apparatus for connecting a load to an electrical power source is provided. The apparatus includes separable contacts selectively connecting the load to the power source when closed and disconnecting the load from the power source when open, a sensor for sensing an electrical current and generating an analog input signal having a first amplitude portion and a second amplitude portion that is different than the first amplitude portion, a compressor circuit electrically coupled to the sensor for amplifying the first amplitude portion of the analog input signal greater than the second portion of the analog input signal, and a microprocessor responsive to a digital input signal, and comprising a memory for storing program signals for decompressing the digital signal and generating a trip signal when the digital signal is greater than a pre-determined limit value.

In still another aspect, a digital program code product for an electronic trip unit is provided. The program code product is configured for decompressing a compressed digital input signal to restore the linearity of the signal including a code segment that receives the compressed digital input signal, a code segment that stores the signal into a register, a code segment that informs an executable program of the signal's arrival in said register, and a code segment that operates on the signal using an algorithm that decompresses the signal and restores the signal linearity.

### BRIEF DESCRIPTION OF DRAWINGS

FIG. 1 is a general schematic of an exemplary electronic trip unit.

FIG. 2 is a flowchart of an exemplary method of expanding a dynamic range of current sensing in an electronic trip unit, such as the electronic trip unit shown in FIG. 1.

### DETAILED DESCRIPTION

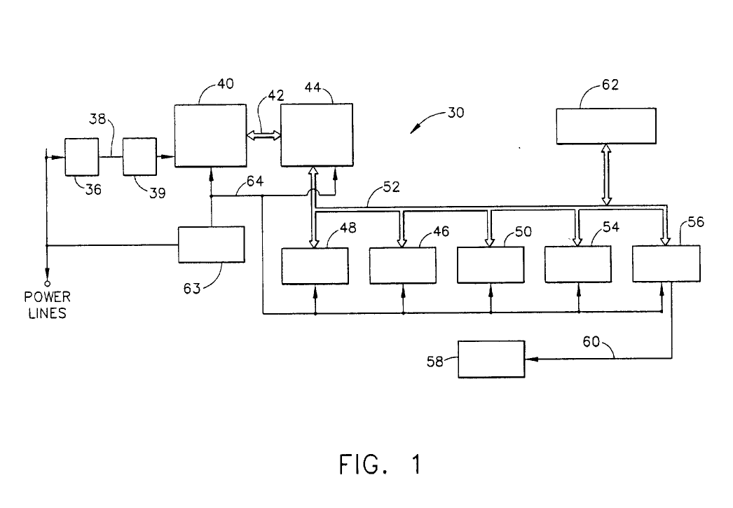

FIG. 1 is a general schematic of an exemplary electronic trip unit 30. Trip unit 30 includes a current sensor 36 which provides analog signals proportional to load current amplitude on a signal line 38. In an alternate embodiment, a voltage sensor (not shown) is used which provides analog signals proportional to voltage amplitude on the power supply lines. The analog current signals on line 38 are presented to a signal conditioner 39 which includes burden resistors (not shown) for current sensor 36 and an amplifier (not shown). The signal is then transmitted to a companding analog to digital (A/D) converter 40 which non-linearly compresses the analog signal by amplifying the smaller amplitude signal more then amplifying larger amplitude signals. In one embodiment, the compression technique uses a Mu-law transfer function. In another embodiment, an A-law transfer function is used. Converter 40 then converts the compressed analog signals to digital signals and the digital signals are transferred over a bus 42 to a microprocessor 44. In one embodiment, microprocessor 44 is of the type commercially available from the Hitachi Electronics Components Group, as part number HD6413001. In the exemplary embodiment, trip unit 30 also includes a random access memory (RAM) 46, a read only memory (ROM) 48 which includes trip unit application code, including initializing parameters, and boot code, and an electronic erasable programmable read only memory (EEPROM) 50, all of which communicate with the microprocessor 44 over a control bus 52. In another embodiment, EEPROM 50 comprises a flash memory whereby data is flashed. In a further embodiment, A/D converter 40, ROM 48, RAM 46, or any combination thereof, are located internally within microprocessor 44. In yet another embodiment, a frequency detection circuit is electrically coupled to current sensor 36 and provides a signal indicative of the frequency of the power line frequency to microprocessor 44. EEPROM 50 is non-volatile such that system information and programming will not be lost during a power interruption or outage. Data is displayed via a display 54 in response to display signals received from microprocessor 44 over control bus 52. An output control device 56, in response to control signals received from microprocessor 44 over control bus 52, controls a trip module 58 via a line 60.

Calibration, testing, programming and other features are accomplished through a communications I/O port 62, which communicates with microprocessor 44 over control bus 52. Limits and settings stored in EEPROM 50 can be altered by downloading desired settings via communications I/O port 62. Such downloaded settings include remotely downloading such data when electronic trip unit 30 is connected to a system computer (not shown), either directly, over telephone lines, or any other suitable connection. A power supply 63 is powered by service electricity, and provides appropriate power through a line 64 to the components of trip unit 30.

In the exemplary embodiment, the application code contained in ROM 48 also includes code for a companding algorithm used within trip unit 30.

Companding enables information to be compressed, sent through a channel to a destination and then expanded upon arrival at the destination. The current sensed by current sensor 36 has a large dynamic range, which could be on the order of one hundred to one. Companding A/D converter 40 includes a non-linear amplifier (not shown) that compresses the current signal from the current sensor. In the non-linear amplifier, larger amplitudes of current are amplified less that the smaller amplitudes. Companding A/D converter 40 also includes an A/D section that digitizes the compressed analog signal. The algorithm used to digitize the signal is variably selectable based on the application and may be modified by downloading new data via communications port 62. One algorithm that may be used is a Mu-law algorithm. Another algorithm that may be used is an A-law algorithm. Mu-law and A-law algorithms are international companding standards, and as such, are well know in the art.

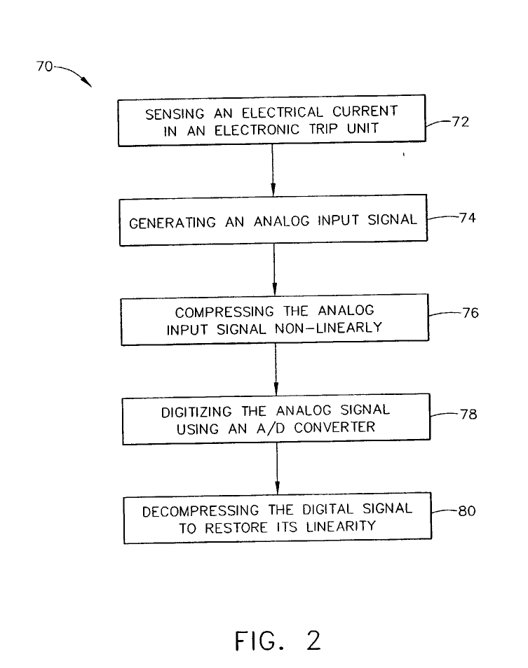

FIG. 2 is a flowchart of an exemplary method of expanding a dynamic range of current sensing in an electronic trip unit, such as the electronic trip unit shown in FIG. 1. The method includes sensing 72 a current flowing to a load proximate the electronic trip unit current sensor. In one embodiment, the sensor is a current transformer. Once the current is sensed, a signal conditioning circuit, including burden resistors and amplifiers, which are known in the art, facilitates generating 74 an analog input signal. The analog input signal is transmitted to the companding A/D converter, where a front end section of the companding A/D converter compresses 76 the analog input signal non-linearly. The compressor transfer function is user selectable and uses a Mu-law, A-law or a custom transfer function.

The compression process is logarithmic, such that the compression increases as the sample signals increase. In other words, the larger amplitude signals are compressed within the compression process more than the smaller amplitude signals. The compressed analog signal is transmitted to the A/D section of the companding A/D converter for digitizing 78 the analog signal into a compressed digital signal. The first step in digitizing 78 the compressed analog signal is to sample the signal at a constant sampling frequency. In one embodiment, the sampling is accomplished using pulse amplitude modulation (PAM). The PAM technique uses the original analog signal to modulate the amplitude of a pulse train that has a constant amplitude and frequency. The optimum sampling frequency is determined by Nyquist's theorem, and is dependent on the frequency to the input power being monitored by the current sensor.

The frequency detection circuit provides a signal input to aid in selecting the proper sampling frequency. Nyquist's theorem is well known and generally states that an original analog signal can be reconstructed if the sampling frequency used is at least twice the highest frequency of the original input signal. If the electronic trip unit is connected to a power source, for example, in Europe, wherein the power grid line frequency is 50 Hz., then a different sampling rate may be needed in the A/D converter, than if the electronic trip unit were connected to a power source in the United States, wherein the power grid line frequency is 60 Hz. In another embodiment, an acceptable compromise in the sampling rate is determined and the frequency detection circuit is not used. After digitizing 78 the compressed analog signal, the digital signal is transmitted to a microcomputer for decompressing 80. The digital signal is received by the microprocessor and stored in a temporary register until the decompressing 80 code segment of the microprocessor's application code operates on the digital signal to restore its linearity. The application code then operates on the decompressed digital signal to effect alarms and trips depending on the value of the decompressed digital signal.

In operation, electronic trip unit 30 continuously monitors current flowing to a load and generates an analog input signal proportional to the current flowing to the load. ETU 30 compresses the analog signal using a variably selectable companding technique before digitizing the signal into a digital input signal. A microprocessor decompresses the digital input signal, restoring the linearity of the digital input signal and actuates a trip device when the digital input signal exceeds pre-determined parameters The above-described method of extending the dynamic range of an electronic trip unit is cost-effective and highly reliable. The method includes the steps of sensing an electrical current flowing through a breaker and generating an analog signal proportional to the current flow, compressing the analog signal non-linearly, digitizing the analog signal and then decompressing the digital signal. The effect of these operations increases the range of input signal currents the ETU can sense and concentrates the precision of the A/D converter on the lower level signals where it is more important. As a result, a method is provided which enables sensing a large dynamic signal range in a cost-effective and reliable manner.

While the invention has been described in terms of various specific embodiments, those skilled in the art will recognize that the invention can be practiced with modification within the spirit and scope of the claims.

1. A method of current sensing in an electronic trip unit, said method comprising:
sensing an electrical current and generating an analog input signal having a first amplitude portion and a second amplitude portion that is different than the first amplitude portion;
compressing the analog input signal non-linearly by amplifying the first amplitude portion of the analog input signal greater than the second amplitude portion of the analog input signal; and
generating a trip signal when any portion of the analog input signal is greater than a pre-determined limit.

2. The method of claim 1 wherein compressing the analog input signal further comprises converting the analog input signal into a digital input signal.

3. The method of claim 2 wherein converting the analog signal further comprises using a mu-law transfer function.

4. The method of claim 2 wherein converting the analog signal further comprises using an A-law transfer function.

5. The method of claim 1 wherein generating a trip signal further comprises:
configuring a microprocessor to be responsive to the digital input signal;
decompressing the digital signal; and
comparing the digital input signal to said stored limit.

6. The method of claim 1 further comprising communicating signals external to the trip unit to a microprocessor for remotely modifying said stored limit value using a digital communications port.

7. The method of claim 1 further comprising detecting an electrical power frequency and generating a signal based on the frequency of electrical power monitored by said electronic trip unit.

8. An electronic trip unit comprising:
a sensor for sensing an electrical current and generating an analog input signal having a first amplitude portion and a second amplitude portion that is different than the first amplitude portion;
a compressor circuit electrically coupled to said sensor for amplifying the first amplitude portion of the analog input signal greater than the second portion of the analog input signal; and
a microprocessor responsive to the digital signal, said microprocessor comprising a memory for storing program signals defining an executable program code for decompressing the digital signal, said microprocessor for generating a trip signal when the digital signal is greater than a pre-determined value.

9. The electronic trip unit of claim 8 wherein said electrical current is a current flowing proximate said sensor to a load.

10. The electronic trip unit of claim 8 wherein the analog input signal is proportional to the amplitude of said sensed electrical current.

11. The electronic trip unit of claim 8 wherein said compressor circuit is a non-linear amplifier circuit.

12. The electronic trip unit of claim 11 wherein said compressor circuit further comprises an analog to digital converter circuit for digitizing the analog input signal into a digital signal using a mu-law transfer function.

13. The electronic trip unit of claim 11 wherein said compressor circuit further comprises an analog to digital converter circuit for digitizing the analog input signal into a digital signal using an A-law transfer function.

14. The electronic trip unit of claim 8 further comprising a communication port for communicating signals external to said trip unit to said microprocessor for remotely modifying a plurality of limit values stored in said memory.

15. The electronic trip unit of claim 8 further comprising a frequency detection circuit electrically coupled to said sensor, said frequency detection circuit generating a signal based on the frequency of electrical power monitored by said electronic trip unit.

16. An electrical apparatus for connecting a load to an electrical power source, said apparatus comprising:
separable contacts selectively connecting the load to the power source when closed and disconnecting the load from the power source when open;
a sensor for sensing an electrical current and generating an analog input signal having a first amplitude portion and a second amplitude portion that is different than the first amplitude portion, a compressor circuit electrically coupled to said sensor for amplifying the first amplitude portion of the analog input signal greater than the second portion of the analog input signal, and a microprocessor responsive to a digital input signal, and comprising a memory for storing program signals for decompressing said digital signal and generating a trip signal when said digital signal is greater than a pre-determined limit value.

17. The electrical apparatus of claim 16 wherein said electrical current is a current flowing proximate said sensor to a load.

18. The electrical apparatus of claim 16 wherein said analog input signal is proportional to the amplitude of said sensed electrical current.

19. The electrical apparatus of claim 16 wherein said compressor circuit is a non-linear amplifier circuit.

20. The electrical apparatus of claim 19 wherein said compressor circuit further comprises an analog to digital converter circuit for digitizing the analog input signal into a digital signal a mu-law transfer function.

21. The electrical apparatus of claim 19 wherein said compressor circuit further comprises an analog to digital converter circuit for digitizing the analog input signal into a digital signal an A-law transfer function.

22. The electrical apparatus of claim 16 further comprising a communication port for communicating signals external to said trip unit to said microprocessor for remotely altering said executable program code and a plurality of limit values stored in said memory.

23. The electrical apparatus of claim 16 further comprising a frequency detection circuit electrically coupled to said sensor, said frequency detection circuit generating a signal based on the frequency of the power source monitored by the electronic trip unit.

24. A digital program code product for an electronic trip unit for decompressing a compressed digital input signal to restore the linearity of said signal comprising:
a code segment that receives the compressed digital input signal;
a code segment that stores the signal into a register;
a code segment that informs an executable program of the signal's arrival in said register; and
a code segment that operates on the signal using an algorithm that decompresses the signal and restores the signal linearity.

25. The digital program code product of claim 24 further comprising a code segment that receives a signal based on the frequency of the power monitored by the electronic trip unit.

26. The digital program code product of claim 24 further comprising a code segment that receives a first user selectable input signal, directing said algorithm to use a mu-law decompression technique, and receives a second user selectable input signal, directing said algorithm to use an A-law decompression technique.
